(19) United States
(12) Patent Application Publication
(10) Pub. No.: US 2025/0015068 A1
(43) Pub. Date: Jan. 9, 2025

(54) OPTOELECTRONIC COMPONENT, OPTOELECTRONIC DEVICE, AND METHOD FOR PRODUCING OPTOELECTRONIC COMPONENTS OR OPTOELECTRONIC DEVICES

(71) Applicant: AMS-OSRAM International GmbH, Regensburg (DE)

(72) Inventor: Siegfried HERRMANN, Neukirchen (DE)

(21) Appl. No.: 18/696,484

(22) PCT Filed: Sep. 21, 2022
(86) PCT No.: PCT/EP2022/076236

§ 371 Date: Mar. 28, 2024

(30) Foreign Application Priority Data
Sep. 30, 2021 (DE) 10 2021 125 416.7

(51) Int. Cl. H01L 25/16; H01L 25/075; H01L 33/62

(52) U.S. Cl. CPC H01L 25/167; H01L 25/0753; H01L 33/62; H01L 2933/0066

(57) ABSTRACT

An optoelectronic component includes an optoelectronic semiconductor chip. The optoelectronic component also includes a control element for controlling an electric current and/or an electric voltage of the optoelectronic semiconductor chip. The optoelectronic semiconductor chip and the control element are arranged one above the other and are mechanically and electrically conductively connected to one another. The optoelectronic component further includes a first connection electrode and a second connection electrode for electrically contacting the optoelectronic component from the outside. The optoelectronic semiconductor chip and the control element are each electrically conductively connected to one of the first and second connection electrodes.

An optoelectronic component, an optoelectronic device, and a method for producing at least one optoelectronic component or at least one optoelectronic device are specified. For example, the optoelectronic component and the optoelectronic device are suitable for emitting electromagnetic radiation, for example in the visible to infrared spectral ranges.

Active matrix displays are known, for example, which contain a matrix of thin-film transistors that are used to control pixels of the display. Each individual pixel can be assigned a circuit with active components, such as transistors, and power supply connections. Previous active matrix displays have been realized, for example, by providing a connection carrier, such as a silicon connection carrier, with integrated active components and power supply connections and arranging thereon a plurality of light-emitting diodes which represent a plurality of pixels. For cost reasons, the aim is to achieve the highest possible integration density of the active components in the connection carrier, so that there is little leeway in the choice of pixel spacing, which is approximately in the sub-micrometer range. However, it is desirable to be able to vary the pixel spacing more depending on the application, so that scalable optoelectronic devices can be realized.

One of the objects to be achieved in the present case is, inter alia, to specify a compact optoelectronic component that enables better scalability. Another object to be achieved in the present case is, inter alia, to specify an optoelectronic device with better scalability. A further object to be achied is, inter alia, to specify an efficient method for producing such an optoelectronic component or such an optoelectronic device.

These objects are achieved, inter alia, by an optoelectronic component, an optoelectronic device, and a method for producing at least one optoelectronic component or at least one optoelectronic device having the features of the independent claims.

Further advantages and embodiments of an optoelectronic component, an optoelectronic device, and a method for producing at least one optoelectronic component or at least one optoelectronic device are the subject of the dependent claims.

According to at least one embodiment of an optoelectronic component, the optoelectronic component comprises an optoelectronic semiconductor chip. The optoelectronic semiconductor chip may be a radiation-emitting or radiation-receiving semiconductor chip.

The optoelectronic semiconductor chip may have a first main surface and a second main surface opposite the first main surface, as well as at least one side surface connecting the first main surface to the second main surface. For example, the first main surface is a radiation exit surface or radiation entrance surface of the optoelectronic semiconductor chip.

According to at least one embodiment, the optoelectronic semiconductor chip comprises a semiconductor body and a first and a second connection element for electrically contacting the semiconductor body. The first connection element can be arranged at the first main surface and the second connection element can be arranged at the second main surface.

The semiconductor body can comprise a first and a second semiconductor region of different conductivity and an active zone arranged between the first and second semiconductor regions, said active zone being designed for generating radiation or for receiving radiation. The first and second semiconductor regions and the active zone can each be formed from one or more semiconductor layers. The semiconductor layers may be layers epitaxially deposited on a growth substrate. The growth substrate can remain in the semiconductor body after the semiconductor layers have been grown or can be at least partially removed. The first semiconductor region can be arranged at the first main surface and the second semiconductor region can be arranged at the second main surface of the semiconductor body.

Materials based on arsenide, phosphide or nitride compound semiconductors, for example, can be used for the semiconductor regions or semiconductor layers of the semiconductor body. “Based on arsenide, phosphide or nitride compound semiconductors” means in the present context that the semiconductor layers contain AlₙGaₘIn₁₋ₙ₋ₘAs, AlₙGaₘIn₁₋ₙ₋ₘP or AlₙGaₘIn₁₋ₙ₋ₘN, with 0≤n≤1, 0≤m≤1 and n+m≤1. This material does not necessarily have to have a mathematically exact composition according to the above formula. Rather, it may include one or more dopants as well as additional constituents that essentially do not change the characteristic physical properties of the AlₙGaₘIn₁₋ₙ₋ₘAs, AlₙGaₘIn₁₋ₙ₋ₘP or AlₙGaₘIn₁₋ₙ₋ₘN materials. For the sake of simplicity, however, the above formula only contains the essential constituents of the crystal lattice (Al, Ga, In, As or P or N), even if these may be partially replaced by small amounts of other substances.

Furthermore, the optoelectronic component may comprise a control element which is provided for controlling an electrical current and/or an electrical voltage of the optoelectronic semiconductor chip. Furthermore, the optoelectronic semiconductor chip and the control element may be mechanically and electrically conductively connected to one another. For example, the control element is a semiconductor component. This means that the same production and connection methods can be used for the control element as for the optoelectronic semiconductor chip.

For example, the optoelectronic semiconductor chip can be switched on by means of the control element so that it emits or detects radiation. In addition, the optoelectronic semiconductor chip can be switched off by means of the control element so that it does not emit or detect radiation. With the integrated control element, the optoelectronic component has a compact design and is suitable, for example, for being used as a pixel in an active matrix display with a dynamic control.

The optoelectronic semiconductor chip and the control element can be arranged one above the other. In this context, “one above the other” means, for example, that the optoelectronic semiconductor chip and the control element follow one another in a vertical direction, which runs transverse, in particular perpendicular, to a main extension plane of a carrier on which they can be arranged.

Furthermore, the optoelectronic component may comprise a first connection electrode and a second connection electrode which are provided for electrically contacting the component from the outside, wherein the optoelectronic semiconductor chip and the control element are each electrically contacted by one of the first and second connection electrodes. This means that separate electrodes are not required for the electrical supply of the single components. Instead, the single components can be electrically supplied by common connection electrodes. For example, the first connection electrode can be formed by a first connection element of the at least one control element or of the at least one optoelectronic semiconductor chip. Furthermore, the second connection electrode can be formed by a second connection element of the at least one control element or of the at least one optoelectronic semiconductor chip. Electrically conductive materials, in particular metals such as Au and Cu, can be used for the connection elements.

According to at least one embodiment, the optoelectronic component comprises
an optoelectronic semiconductor chip,
a control element which is provided for controlling an electric current and/or an electric voltage of the optoelectronic semiconductor chip, wherein the optoelectronic semiconductor chip and the control element are arranged one above the other and are mechanically and electrically conductively connected to one another, and
a first connection electrode and a second connection electrode which are provided for electrically contacting the component from the outside, wherein the optoelectronic semiconductor chip and the control element are each electrically contacted by one of the first and second connection electrodes.

According to at least one advantageous configuration, the optoelectronic component has lateral dimensions which have values in the single-digit or double-digit micrometer range. For example, the optoelectronic component can have lateral dimensions of 10 μm, with deviations of ±10% being possible. The optoelectronic semiconductor chip can be a micro LED. The control element can also have lateral dimensions which have values in the single-digit or double-digit micrometer range.

According to at least one embodiment, the control element does not project laterally beyond the optoelectronic semiconductor chip. In this context, “lateral” denotes, for example, at least one lateral direction, said lateral direction running parallel to the main extension direction of a possible carrier and perpendicular to the vertical direction. The lateral dimensions are determined parallel to the lateral directions.

The control element can be arranged laterally offset to the optoelectronic semiconductor chip. In this context, “laterally offset” means, for example, that there is a lateral distance between a main axis of the optoelectronic semiconductor chip and a main axis of the control element. For example, the control element can be arranged downstream of the first main surface or the radiation exit surface or radiation entrance surface of the optoelectronic semiconductor chip in a main radiation direction. The control element can be arranged laterally offset to the optoelectronic semiconductor chip so that the first main surface is at most partially covered by the control element, thus reducing radiation losses. Alternatively, the control element and the optoelectronic semiconductor chip can be arranged without lateral offset with respect to each other. This can be the case, for example, if the control element is located on a side of the optoelectronic semiconductor chip facing away from the radiation exit surface or radiation entrance surface.

According to at least one embodiment, the first connection electrode and the second connection electrode are arranged at least sectionally on opposite sides of the component. This structure corresponds to the structure of a vertical diode, for example.

Alternatively, the first connection electrode and the second connection electrode can be arranged on the same side of the component. This structure corresponds to the structure of a horizontal diode, for example.

According to at least one embodiment, the control element comprises a resistive layer having a variable electrical resistance, wherein the resistive layer contains an oxide. For example, ZnO and/or NiO can be used for the resistive layer. Preferably, the resistive layer is formed from a non-conductive oxide which has impurities whose electrical resistance can be varied between two extreme values by changing an electrical voltage. Such a control element follows the principle of a so-called ReRAM (Resistive Random Access Memory) as described, for example, in the article “Array-level stability enhancement of 50 nm AlₓO_{y} ReRam”, Iwasaki et al., Solid State Electronics 114 (2015)1-8.

According to at least one embodiment, the control element comprises a transistor. For the transistor, MISFET (Metal Insulator Semiconductor Field Effect Transistor) transistor types such as n-channel MOSFETs (Metal Oxide Semiconductor Field Effect Transistors) or three-dimensional transistors such as FinFETs (Fin Field Effect Transistors) can be used. In this and other embodiments, the optoelectronic component may comprise a third connection electrode, which is provided for electrically contacting the component from the outside. In each case, one of the three connection electrodes is provided for a source contact, a gate contact and a drain contact.

According to at least one embodiment, the optoelectronic semiconductor chip and the control element are electrically conductively connected to one another by means of an electrically conductive connecting means, wherein the connecting means contains at least one of the following materials: metal, metal compound, plastic material, TCO (Transparent Conductive Oxide).

According to at least one embodiment of an optoelectronic device, the optoelectronic device comprises at least one optoelectronic component of the above-mentioned type and a carrier on which the at least one optoelectronic component is arranged. The carrier may comprise a base body which, for example, contains or consists of a semiconductor material, such as silicon.

Furthermore, the optoelectronic device may comprise a first electrical contact structure to which the first connection electrode of the at least one optoelectronic component is electrically conductively connected. In addition, the optoelectronic device may comprise a second electrical contact structure to which the second connection electrode of the at least one optoelectronic component is electrically conductively connected. If the optoelectronic component comprises a third connection electrode, the optoelectronic device can correspondingly comprise a third electrical contact structure to which the third connection electrode is electrically conductively connected. The electrical contact structures can be arranged on the base body. At least one of the electrical contact structures can be part of the carrier. Electrically conductive materials, in particular metals such as Au and Cu, can be used for the contact structures.

For example, a side of the optoelectronic device facing away from the carrier is a radiation exit side of the optoelectronic device.

According to at least one embodiment of the optoelectronic device, the control element is arranged on the side of the optoelectronic semiconductor chip of the at least one optoelectronic component facing away from the carrier.

Alternatively, the control element can be arranged between the carrier and the optoelectronic semiconductor chip of the at least one optoelectronic component.

The optoelectronic components can each be controlled individually by means of the integrated control elements.

Furthermore, the lateral distances between the optoelectronic components can be freely selected so that the optoelectronic device is scalable and, for example, high pixel densities can be achieved.

The method described below is suitable for producing at least one optoelectronic component of the above-mentioned type or at least one optoelectronic device of the above-mentioned type. Features described in connection with the component or device can therefore also be used for the method and vice versa.

According to at least one embodiment of a method for producing at least one optoelectronic component or at least one optoelectronic device, the method comprises a step of providing at least one control element. Furthermore, the method may comprise providing at least one optoelectronic semiconductor chip. The at least one optoelectronic semiconductor chip may be arranged on a detachable intermediate carrier. Furthermore, the method may comprise arranging the at least one control element on the at least one optoelectronic semiconductor chip and connecting the at least one control element mechanically and electrically to the at least one optoelectronic semiconductor chip. In addition, the method may comprise defining, that is, determining or forming, at least one first connection electrode and at least one second connection electrode.

According to at least one embodiment of a method for producing at least one optoelectronic component or at least one optoelectronic device, the method comprises the following steps:
Providing at least one control element,
providing at least one optoelectronic semiconductor chip,
arranging the at least one control element on the at least one optoelectronic semiconductor chip, and connecting the at least one control element mechanically and electrically conductively to the at least one optoelectronic semiconductor chip,
defining at least one first connection electrode and at least one second connection electrode.

For example, the method steps are carried out in the specified order.

According to at least one embodiment, for producing the at least one optoelectronic device, at least one of the two electrical contact structures is produced after arranging the at least one optoelectronic component on the carrier.

The optoelectronic component/device is particularly suitable for active matrix displays, micro LED displays, transceiver modules and headlights in applications such as video glasses, virtual reality projectors and data transmission. The optoelectronic component/device is characterized by a high pixel density, low energy consumption and a comparatively simple electrical circuitry.

Further advantages, advantageous embodiments and further developments will become apparent from the exemplary embodiments described below in conjunction with the figures.

In the figures:

FIGS. 1 and 3 to 6 show schematic cross-sectional views of optoelectronic components according to various exemplary embodiments,

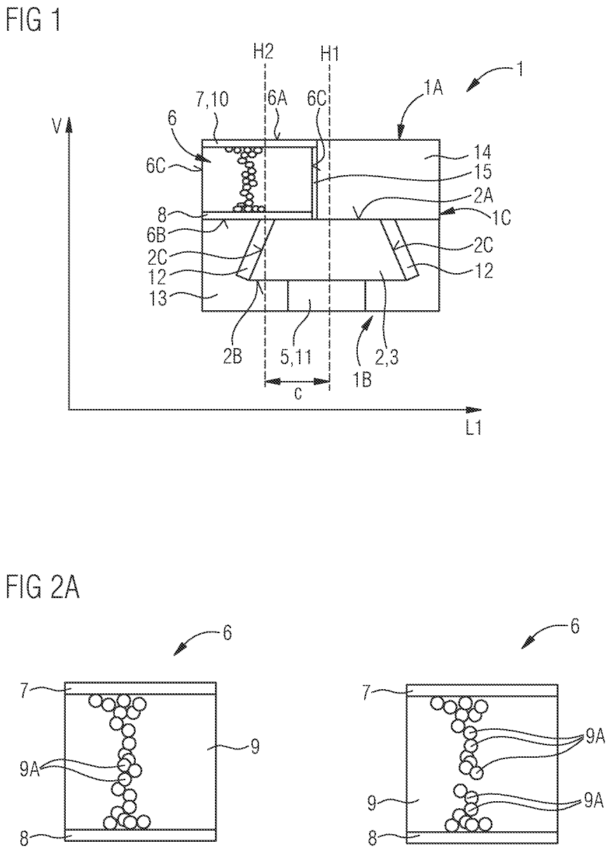

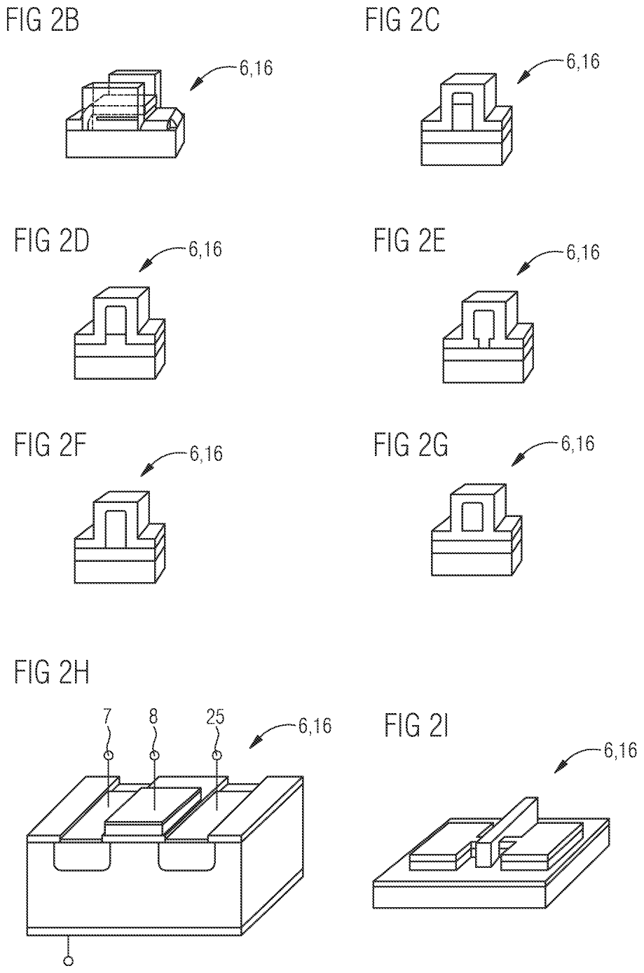

FIG. 2A shows schematic cross-sectional views and FIGS. 2B to 2I show schematic perspective views of control elements according to various exemplary embodiments,

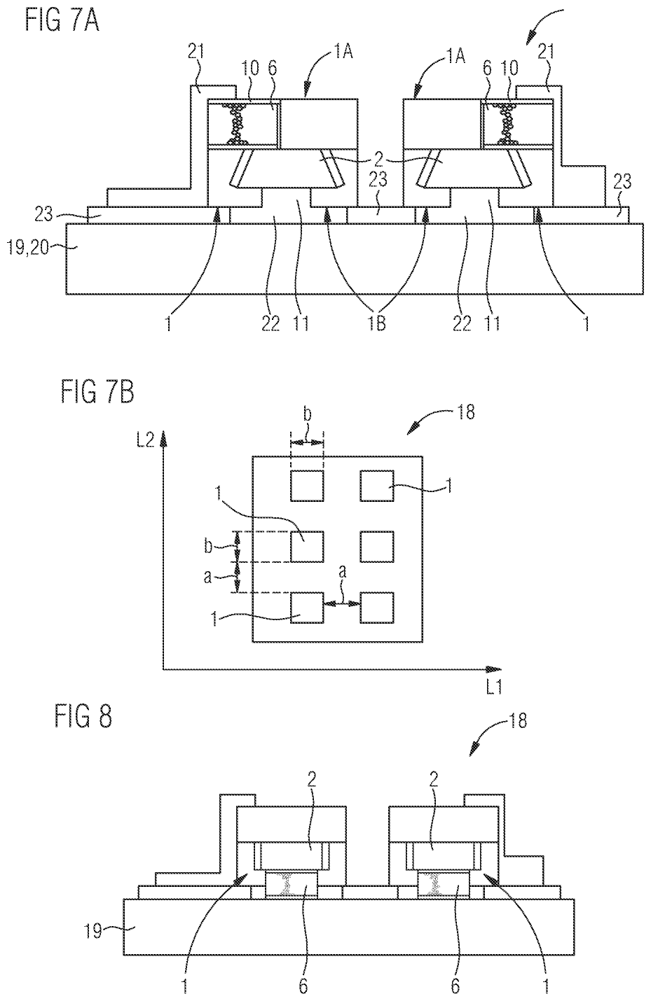

FIG. 7A shows a schematic cross-sectional view and FIG. 7B shows a schematic top view of an optoelectronic device according to an exemplary embodiment,

FIG. 8 shows a schematic cross-sectional view of an optoelectronic device according to a further exemplary embodiment,

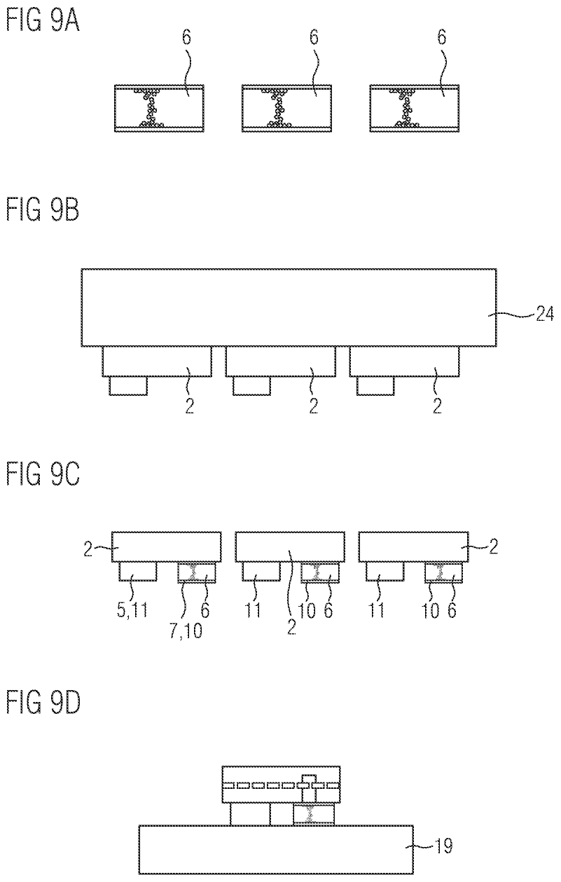

FIGS. 9A to 9D show various steps of a method for producing optoelectronic components or optoelectronic devices according to an exemplary embodiment.

In the exemplary embodiments and figures, identical, similar or similarly acting elements can each be provided with the same reference signs. The elements shown and their relative sizes are not necessarily to be regarded as true to scale; rather, individual elements may be shown in exaggerated size for better visualization and/or understanding.

FIG. 1 shows a first exemplary embodiment of an optoelectronic component 1. The optoelectronic component 1 comprises an optoelectronic semiconductor chip 2 having a first main surface 2A and a second main surface 2B opposite the first main surface 2A as well as a plurality of side surfaces 2C which connect the first main surface 2A to the second main surface 2B.

The optoelectronic semiconductor chip 2 can be a radiation-emitting semiconductor chip 2 which comprises a semiconductor body 3 with an active zone designed for emitting radiation. As mentioned above, materials based on arsenide, phosphide or nitride compound semiconductors can be used for the semiconductor body 3 or the semiconductor layers contained therein. For electrical contacting, the optoelectronic semiconductor chip 2 can comprise a first connection element (not shown), which is arranged at the first main surface 2A, and a second connection element 5, which is arranged at the second main surface 2B.

The optoelectronic component 1 further comprises a control element 6 provided for controlling an electric current and/or an electric voltage of the optoelectronic semiconductor chip 2. The control element 6 may comprise a first main surface 6A and a first connection element 7 arranged at the first main surface 6A. Further, the control element 6 may comprise a second main surface 6B and a second connection element 8 arranged at the second main surface 6B. In addition, the control element 6 comprises several side surfaces 6C which connect the first main surface 6A to the second main surface 6B.

The optoelectronic semiconductor chip 2 and the control element 6 are mechanically connected to one another by means of a connecting means (not shown), for example by means of a solder or an adhesive. Furthermore, the optoelectronic semiconductor chip 2 and the control element 6 are electrically conductively connected to one another. The optoelectronic semiconductor chip 2 and the control element 6 can form a series connection, for example.

The optoelectronic semiconductor chip 2 and the control element 6 are arranged one above the other, wherein the control element 6 follows the optoelectronic semiconductor chip 2 in a vertical direction V and is arranged downstream of the first main surface 2A of the optoelectronic semiconductor chip 2 in the vertical direction V. A main radiation direction of the optoelectronic semiconductor chip 2 may be parallel to the vertical direction V.

Furthermore, the control element 6 is arranged laterally offset to the optoelectronic semiconductor chip 2. This means that there is a lateral distance c between a main axis H1 of the optoelectronic semiconductor chip 2 and a main axis H2 of the control element 6, each of which runs parallel to the vertical direction V. “Lateral” here means parallel to a lateral direction L1 which runs transverse, in particular perpendicular, to the vertical direction V. In this case, the first main surface 2A, which may be a radiation exit surface, is only partially covered by the control element 6, so that radiation losses can be reduced.

The optoelectronic component 1 comprises a first connection electrode 10 and a second connection electrode 11, which are provided for electrically contacting the optoelectronic component 1 from the outside. The control element 6 is electrically contacted by the first connection electrode 10, while the semiconductor chip 2 is electrically contacted by the second connection electrode 11. The first connection electrode 10 is the first connection element 7 of the control element 6, while the second connection electrode 11 is the second connection element 5 of the semiconductor chip 2. The first connection electrode 10 can form an n-side contact and the second connection electrode 11 can form a p-side contact of the component 1. The first connection electrode 10 and the second connection electrode 11 are arranged on opposite sides of the component 1, namely a front side 1A and a rear side 1B.

The optoelectronic component 1 may comprise a passivation 12 which covers the side surfaces 2C of the semiconductor chip 2 and provides electrical insulation at the side surfaces 2C. The passivation 12 may contain a dielectric material, such as SiO2.

Furthermore, the optoelectronic component 1 comprises an encapsulation element 13, which is arranged laterally downstream of the optoelectronic semiconductor chip 2 and is flush with the first and second main surfaces 2A, 2B of the semiconductor chip 2. Furthermore, the encapsulation element 13 is flush with a side surface 6C of the control element 6. Dielectric, radiation-transmissive materials, such as spin-on glass, can be used for the encapsulation element 13.

Furthermore, the optoelectronic component 1 may comprise a contact element 14 which is arranged vertically downstream of the semiconductor chip 2 and laterally downstream of the control element 6, the contact element 14 being flush laterally with the encapsulation element 13 and vertically with the first main surface 6A of the control element 6.

The optoelectronic component 1 thus advantageously has flat side surfaces 1C and flat surfaces on the front and rear sides 1A, 1B.

For example, transparent electrically conductive materials such as TCOs (Transparent Conductive Oxides) can be used for the contact element 14. The contact element 14 is electrically conductively connected to the first connection electrode 10 and improves the electrical contact to the semiconductor chip 2. An electrically insulating layer 15 is advantageously arranged between the control element 6 and the contact element 14.

The optoelectronic component 1 is similar in structure to a vertical diode. With the integrated control element 6, it has a compact shape with lateral dimensions that have values in the single-digit or double-digit micrometer range, where the lateral dimensions are determined parallel to the lateral direction L1 and to a further lateral direction L2 (not shown) which runs perpendicular to the lateral direction L1 and to the vertical direction V. The optoelectronic semiconductor chip 2 can also have lateral dimensions that have values in the single-digit or double-digit micrometer range. For example, the optoelectronic semiconductor chip 2 is a micro LED.

By means of the control element 6, the optoelectronic component 1 or the optoelectronic semiconductor chip 2 can be individually controlled and is suitable, for example, for being used as a pixel in an active matrix display with a dynamic control.

Various exemplary embodiments of a control element 6 are described in connection with FIGS. 2A to 2I.

As shown in FIG. 2A, the control element 6 may comprise a resistive layer 9 having a variable electrical resistance.

The resistive layer 9 contains, for example, a non-conductive oxide, such as ZnO and/or NiO, with impurities 9A whose electrical resistance can be varied between two extreme values by changing an electrical voltage (see FIG. 2A left:

small electrical resistance, FIG. 2B: large electrical resistance). Such a control element 6 follows the principle of a so-called ReRAM (Resistive Random Access Memory) as described, for example, in the article “Array-level stability enhancement of 50 nm AlₓO_{y} ReRam”, Iwasaki et al., Solid State Electronics 114 (2015)1-8. Such a control element 6 enables, for example, fast modulation of the brightness of the semiconductor chip 2 and is associated with low switching currents and voltages, so that low power losses occur due to the circuit. The control element 6 is programmable during operation, its programming time being fractions of seconds and being small compared to a illumination time of the semiconductor chip 2.

Furthermore, the control element 6 may comprise a transistor 16 of the type of transistors shown in FIGS. 2B to 21. The optoelectronic component 1 may comprise a third connection electrode 25 (see FIG. 2H), which is provided for electrically contacting the component 1 from the outside.

FIGS. 2B to 2G show MOSFETs (Metal Oxide Semiconductor Field Effect Transistors) that comprise more than one gate, wherein FIG. 2B shows a so-called Flexfet, FIG. 2C a so-called pi-gate transistor, FIG. 2D a so-called tri-gate transistor, FIG. 2E a so-called FinFET, FIG. 2F a so-called Q-gate transistor and FIG. 2G a so-called GAAFET. FIG. 2H shows a so-called n-channel MOSFET. FIG. 2I shows a FinFET.

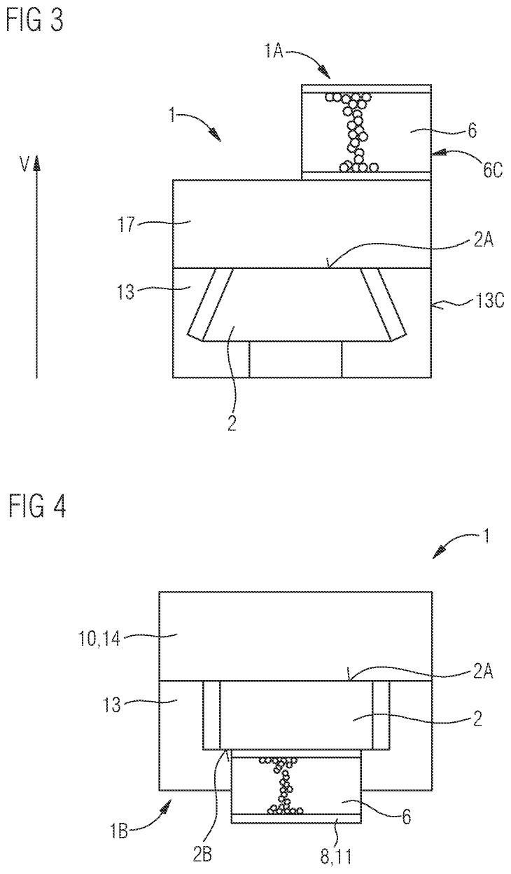

FIG. 3 shows a further exemplary embodiment of an optoelectronic component 1, in which the optoelectronic semiconductor chip 2 is laterally surrounded by an encapsulation element 13 as in the first exemplary embodiment. The control element 6 follows the first main surface 2A of the semiconductor chip 2 in the vertical direction V and is arranged laterally offset to the semiconductor chip 2, the control element 6 being flush with a side surface 13C of the encapsulation element 13. Between the control element 6 and the semiconductor chip 2, a connecting means 17 is arranged, which is flush with a side surface 6C of the control element 6 and for which a TCO can be used, for example. In this exemplary embodiment, the optoelectronic component 1 has a stepped design at its front side 1A.

In addition, the optoelectronic component 1 has all the properties, features and advantages mentioned in connection with the further exemplary embodiments.

FIG. 4 shows a further exemplary embodiment of an optoelectronic component 1, in which the optoelectronic semiconductor chip 2 is laterally surrounded by an encapsulation element 13. The control element 6 is arranged on the second main surface 2B of the semiconductor chip 2. The semiconductor chip 2 is arranged downstream of the control element 6 in the vertical direction V, with the optoelectronic component 1 resembling a vertical diode in terms of its structure. The control element 6 does not project laterally beyond the optoelectronic semiconductor chip 2 and is partially covered laterally by the encapsulation element 13. A contact element 14 is arranged on the first main surface 2A of the semiconductor chip 2, serving as the first connection electrode 10, which is electrically conductively connected, for example, to the p-side of the semiconductor chip 2. Electrically conducting, radiation-transmissive materials such as TCOs can be used for the contact element 14. A second connection element 8 of the control element 6, which is arranged at a rear side 1B of the component 1, serves as the second connection electrode 11.

In addition, the optoelectronic component 1 has all the properties, features and advantages mentioned in connection with the further exemplary embodiments.

FIG. 5 shows a further exemplary embodiment of an optoelectronic component 1, in which the first connection electrode 10 and the second connection electrode 11 are arranged on the same side, for example the rear side 1B of the component 1. The semiconductor chip 2 comprises a second connection element 5 at the second main surface 2B, said second connection element 5 serving as the second connection electrode 11. The second connection element 5 can form a p-side connection of the semiconductor chip 2. Furthermore, the semiconductor chip 2 comprises a depression in the semiconductor body 3 which, starting from the second main surface 2B, extends through the active zone 3A of the semiconductor body 3 and ends in front of the first main surface 2A. The first connection element 4 of the semiconductor chip 2 is arranged in the depression and forms, for example, an n-side connection of the semiconductor chip 2. The control element 6 is arranged on the second main surface 2B of the semiconductor chip 2, laterally offset with respect to the latter, wherein the control element 6 does not project laterally beyond the semiconductor chip 2 and does not project vertically beyond the second connection element 5. The first connection element 4 of the semiconductor chip 2 is electrically conductively connected to the second connection element 8 of the control element 6. The first connection element 7 of the control element 6 forms a first connection electrode 10 of the optoelectronic component 1.

The optoelectronic component 1 is similar in structure to a horizontal diode.

In addition, the optoelectronic component 1 has all the properties, features and advantages mentioned in connection with the further exemplary embodiments.

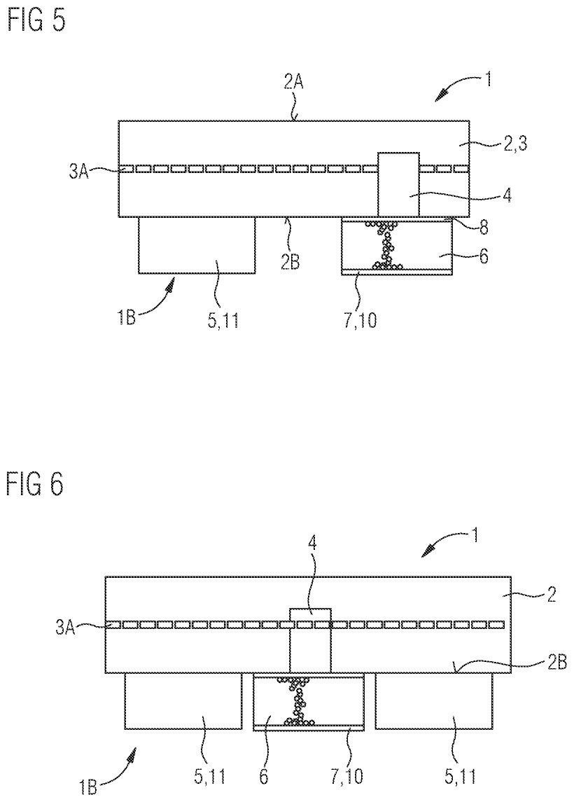

FIG. 6 shows a further exemplary embodiment of an optoelectronic component 1, in which the first connection electrode 10 and the second connection electrode 11 are arranged on the same side, for example the rear side 1B of the component 1. Compared to the preceding exemplary embodiment, the control element 6 is arranged without any lateral offset to the semiconductor chip 2. The control element 6 is arranged centrally on the second main surface 2B of the semiconductor chip 2.

In addition, the optoelectronic component 1 has all the properties, features and advantages mentioned in connection with the further exemplary embodiments.

FIGS. 7A and 7B show an exemplary embodiment of an optoelectronic device 18 comprising a plurality of optoelectronic components 1 as described, for example, in connection with the exemplary embodiment of FIG. 1.

Furthermore, the optoelectronic device 18 comprises a carrier 19 on which the optoelectronic components 1 are arranged each with their rear side 1B. The control elements 6 are each arranged on the side of the optoelectronic semiconductor chips 2 facing away from the carrier 19.

The carrier 19 comprises a base body 20, which for example contains or consists of a semiconductor material, such as silicon.

Furthermore, the optoelectronic device 18 comprises a first electrical contact structure 21, to which the first connection electrodes 10 of the optoelectronic components 1 are each electrically conductively connected. The first electrical contact structure 21 extends in each case from the front side 1A of the optoelectronic components 1 to the carrier 19.

Furthermore, the optoelectronic device 18 comprises a second electrical contact structure 22, to which the second connection electrodes 11 of the optoelectronic components 1 are each electrically conductively connected. The second electrical contact structure 22 is arranged on the base body 20 and can be a part of the carrier 19.

For electrical insulation between the electrical contact structures 21, 22, the optoelectronic device 18 comprises an electrically insulating layer 23 which contains, for example, a dielectric material such as Al2O3.

The optoelectronic device 18 is, for example, an active matrix display, in particular a micro LED display. By means of the electrical contact structures 21, 22 and the control elements 6, it is possible for the semiconductor chips 2 to be controlled in a simple manner, in particular without a transistor submount and with fewer control lines per semiconductor chip 2, and to light up simultaneously and independently of one another. If the control elements 6 are designed as ReRAMs, the resistance of the components 1 can be programmed accordingly for selective control during operation.

As can be seen from FIG. 7B, the optoelectronic components 1 can be arranged with lateral distances a in the micrometer range, preferably with values greater than 1 μm. Furthermore, the optoelectronic components 1 can have lateral dimensions b of 10 μm, with deviations of ±10% being possible. The lateral distances a and lateral dimensions b are determined parallel to the lateral directions L1, L2, which are each parallel to a main extension direction or main extension plane of the carrier 19.

In addition, the optoelectronic device 18 has all the properties, features and advantages mentioned in connection with the further exemplary embodiments.

FIG. 8 shows an exemplary embodiment of an optoelectronic device 18 which comprises several optoelectronic components 1 as described, for example, in connection with the exemplary embodiment of FIG. 4. Here, the control elements 6 are each arranged between the carrier 19 and the optoelectronic semiconductor chips 2.

In addition, the optoelectronic device 18 has all the properties, features and advantages mentioned in connection with the further exemplary embodiments.

FIGS. 9A to 9D show various steps of an exemplary embodiment of a method for producing optoelectronic components 1 as described above, for example in connection with FIG. 5, or optoelectronic devices 18.

The method comprises the step of providing control elements 6 (see FIG. 9A).

Furthermore, the method comprises the step of providing optoelectronic semiconductor chips 2, for example on a removable intermediate carrier 24 (see FIG. 9B).

Furthermore, the method comprises the step of arranging each of the control elements 6 on an optoelectronic semiconductor chip 2. The control elements 6 can be arranged on the semiconductor chips 2 by means of a transfer process. Furthermore, the method comprises the step of mechanically and electrically connecting the control elements 6 to the respective optoelectronic semiconductor chip 2 (see FIG. 9C).

In addition, the method comprises defining first connection electrodes 10 and second connection electrodes 11, wherein the first connection electrodes 10 can be formed by the first connection elements 7 of the control elements 6 and the second connection electrodes 11 can be formed by the second connection elements 5 of the semiconductor chips 2. The optoelectronic components 1 produced in this way can be arranged individually or together on a carrier 19 (see FIG. 9D). The lateral distances between the optoelectronic components 1 can be freely selected, so that scalable optoelectronic devices 18 can be produced by means of the optoelectronic components 1.

The invention is not limited by the description based on the exemplary embodiments. Rather, the invention includes any new feature as well as any combination of features, which includes in particular any combination of features in the patent claims, even if this feature or combination itself is not explicitly stated in the patent claims or embodiments.

This patent application claims the priority of German patent application Ser. No. 10/202,1125416.7, the disclosure of which is hereby incorporated by reference.

### LIST OF REFERENCE SIGNS

1 optoelectronic component
1A front side
1B rear side
1C side surface
2 optoelectronic semiconductor chip
2A first main surface
2B second main surface
2C side surface
3 semiconductor body
3A active zone
4 first connection element of the semiconductor chip
5 second connection element of the semiconductor chip
6 control element
6A first main surface
6B second main surface
6C side surface
7 first connection element of the control element
8 second connection element of the control element
9 resistive layer
9A impurity
10 first connection electrode
11 second connection electrode
12 passivation
13 encapsulation element
13C side surface
14 contact element
15 electrically insulating layer
16 transistor
17 connecting means
18 optoelectronic device
19 carrier
20 base body
21 first electrical contact structure
22 second electrical contact structure
23 electrically insulating layer
24 intermediate carrier
25 third connection electrode
a, c lateral distance
b lateral dimension
L, L1, L2 lateral direction
V vertical direction
H1, H2 main axis

1. An optoelectronic component comprising
an optoelectronic semiconductor chip,
a control element which is provided for controlling an electric current and/or an electric voltage of the optoelectronic semiconductor chip and comprises a resistive layer having a variable electrical resistance, wherein the optoelectronic semiconductor chip-(2) and the control element are arranged one above the other and are mechanically and electrically conductively connected to one another, and wherein the optoelectronic semiconductor chip and the control element are single components, and
a first connection electrode and a second connection electrode which are provided for electrically contacting the optoelectronic component from the outside, wherein the optoelectronic semiconductor chip and the control element are each electrically contacted by one of the first and second connection electrodes.

2. The optoelectronic component according to claim 1, which has lateral dimensions having values in the single-digit or double-digit micrometer range.

3. The optoelectronic component according to claim 1, wherein the control element does not project laterally beyond the optoelectronic semiconductor chip.

4. The optoelectronic component according to claim 1, wherein the control element is arranged laterally offset to the optoelectronic semiconductor chip.

5. The optoelectronic component according to claim 1, wherein the first connection electrode and the second connection electrode are arranged at least sectionally on opposite sides of the component.

6. The optoelectronic component according to claim 1, wherein the first connection electrode and the second connection electrode are arranged on the same side of the component.

7. The optoelectronic component according to claim 1, wherein the resistive layer contains an oxide.

8. The optoelectronic component according to claim 1, wherein the control element comprises a transistor.

9. The optoelectronic component according to claim 8, which comprises a third connection electrode provided for electrically contacting the component from the outside.

10. The optoelectronic component according to claim 1, wherein the optoelectronic semiconductor chip and the control element are electrically conductively connected to one another by means of an electrically conductive connecting means, wherein the connecting means contains at least one of the following materials: metal, metal compound, plastic material, TCO.

11. An optoelectronic device comprising
at least one optoelectronic component according to claim 1,
a carrier on which the at least one optoelectronic component is arranged,
a first electrical contact structure to which the first connection electrode of the at least one optoelectronic component is electrically conductively connected, and
a second electrical contact structure to which the second connection electrode of the at least one optoelectronic component is electrically conductively connected.

12. The optoelectronic device according to claim 11, wherein the control element is arranged on a side of the optoelectronic semiconductor chip of the at least one optoelectronic component facing away from the carrier.

13. The optoelectronic device according to claim 11, wherein the control element is arranged between the carrier and the optoelectronic semiconductor chip of the at least one optoelectronic component.

14. A method for producing at least one optoelectronic component according to claim 1, comprising the following steps:
providing at least one control element, which comprises a resistive layer having a variable electrical resistance,
providing at least one optoelectronic semiconductor chip,
arranging the at least one control element on the at least one optoelectronic semiconductor chip, and connecting the at least one control element mechanically and electrically conductively to the at least one optoelectronic semiconductor chip,
defining at least one first connection electrode and at least one second connection electrode.

15. The method according to claim 14, wherein for producing the at least one optoelectronic device at least one of the two electrical contact structures is produced after arranging the at least one optoelectronic component on the carrier.

16. A method for producing at least one optoelectronic device according to claim 11, comprising the following steps:
providing at least one control element, which comprises a resistive layer having a variable electrical resistance,
providing at least one optoelectronic semiconductor chip,
arranging the at least one control element on the at least one optoelectronic semiconductor chip, and connecting the at least one control element mechanically and electrically conductively to the at least one optoelectronic semiconductor chip,
defining at least one first connection electrode and at least one second connection electrode.

17. The method according to claim 16, wherein for producing the at least one optoelectronic device at least one of the two electrical contact structures is produced after arranging the at least one optoelectronic component on the carrier.
